(19) United States
(12) Patent Application Publication
(10) Pub. No.: US 2007/0108538 A1
(43) Pub. Date: May 17, 2007

(54) Semiconductor device and method for manufacturing the same

(76) Inventor: Masato Koyama, Kanagawa-Ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/589,829

(22) Filed: Oct. 31, 2006

(30) Foreign Application Priority Data
Nov. 14, 2005 (JP) 2005-328929

(51) Int. Cl. H01L 29/94

(52) U.S. Cl. 257/412

(57) ABSTRACT

A semiconductor device is provided that has MIS transistors with metal gates that can prevent an increase in the number of manufacturing steps as much as possible and also restrain difficulties in the manufacturing conditions. This semiconductor device has a substrate; and an n-channel MIS transistor including: a p-type semiconductor layer formed on the substrate; a pair of n-type source/drain regions formed in the p-type semiconductor layer and isolated each other; a first gate insulating film formed on the p-type semiconductor layer and located between the pair of n-type source/drain regions; and a first gate electrode formed on the first gate insulating film and containing an alloy of a rare-earth metal and a metal selected from the group consisting of Ru, Pt, and Rh.

### CROSS-REFERENCE TO RELATED APPLICATION

This application is based upon and claims the benefit of priority from prior Japanese Patent Application No. 2005-328929 filed on Nov, 14, 2005 in Japan, the entire contents of which are incorporated herein by reference.

### BACKGROUND OF THE INVENTION

1. Field of the Invention

The present invention relates to a semiconductor device and a method for manufacturing the semiconductor device.

2. Related Art

Silicon CMIS (Complementary Metal Insulator Semiconductor) devices are the most essential devices to form the hearts of high-speed, low-power-consumption system LSI products.

When a next-generation CMIS device having a deep submicron gate length is manufactured, there is a high possibility that the gate electrodes of the MIS transistors constituting the CMIS device cannot be formed with silicon, which has been used in previous generations. The primary reason of this is the depletion of the gate electrodes. The solid solubility limit of impurities (dopant) with respect to silicon is approximately 1×10²⁰ cm−³. Therefore, if the gate electrodes are made of silicon, a depletion layer forms at each gate electrode/gate insulator interface. Since the depletion layer becomes a capacitance connected in series to the gate insulating film between the gate electrode and the channel, the gate capacitance of each MIS transistor has the capacitance of the depletion layer substantially added to the capacitance of the gate insulating film. The additional capacitance is equivalent to approximately 0.3 nm to 0.5 nm in terms of the thickness of the silicon oxide film forming the gate insulating film. This causes the problem of a decrease in current drivability of the transistor device.

When each MIS transistor has a deep submicron gate length in the future, the silicon oxide equivalent film thickness of each gate insulating film is estimated to be 1.5 nm or smaller. As a result, the capacitance of the depletion layer makes up 20% of the capacitance of the gate insulating film, which cannot be ignored.

To counter this problem, metals and metal compounds have been used as gate electrodes in recent years. This is called the “metal gate technique”.

By the metal gate technique, a depletion layer is not formed in each gate electrode in principle, and accordingly, a decrease in current drivability of each MIS transistor due to the depletion layer as in the case of a silicon gate structure is not caused.

JP-A 2004-165346 (KOKAI) discloses a technique for solving the above problem by forming a CMOS with conventional polysilicon gate electrodes and replacing each silicon gate with a metal material such as Al, Pt, Cu, Au, Ag, Pd, or Ni in a back end of line process, for example. By this technique, however, the silicon gates of the n-channel MIS transistor and the p-channel MIS transistor need to be replaced with metal materials having work functions suitable for the respective transistors in separate procedures from each other. This appears to be possible in principle, but the problems of an increase in the number of processing steps and the complication in the processing have not been solved.

In this manner, the metal gate technique has overcome the performance limits of the silicon gate technique, but produced new problems that are unique to the metal gate technique.

The first problem is the necessity of threshold voltage control through appropriate selection of gate electrode material. By the conventional silicon gate technique, p+-silicon is used for the p-channel MIS transistor, and n+-silicon is used for the n-channel MIS transistor, so that a reasonably low threshold voltage can be set for both channel transistors. By the metal gate technique, on the other hand, it is necessary to find metal materials with the same work functions as p+-silicon and n+-silicon, and use such metal materials for the channel transistors.

After the gate metals with suitable work functions for solving the first problem are found, the second problem arises in the manufacturing of a CMIS transistor. By the conventional silicon gate technique, the gate electrodes of both channel transistors are manufactured at the same time. By the metal gate technique, however, it is necessary to process two kinds of metals having different work functions from each other in separate procedures. As a result, the number of manufacturing procedures becomes larger than that by the conventional silicon gate technique, and the manufacturing conditions become more complicated. Such problems greatly hinder the practical use of the metal gate technique.

As described above, the metal gate technique developed to overcome the performance limits of the conventional silicon gate technique has the two technical problems of the difficult selection of materials with suitable work functions and the complication of the CMIS device manufacturing. The metal gate technique cannot be put into practical use unless these problems are solved.

To increase the current drivability of transistors and produce high-speed silicon CMIS devices, the metal gate technique should replace the conventional silicon gate technique. However, an effective method has not been developed to process two different gate electrode materials having work functions suitable for the threshold voltage control in both channel transistors and form the gate electrodes of a CMIS transistor by a manufacturing technique similar to the conventional technique.

### SUMMARY OF THE INVENTION

A semiconductor device according to a first aspect of the present invention includes: a substrate; and an n-channel MIS transistor including: a p-type semiconductor layer formed on the substrate; a pair of n-type source/drain regions formed in the p-type semiconductor layer and isolated from each other; a first gate insulating film formed on the p-type semiconductor layer and located between the pair of n-type source/drain regions; and a first gate electrode formed on the first gate insulating film and containing an alloy of a rare-earth metal and a metal selected from the group consisting of Ru, Pt, and Rh.

A semiconductor device according to a second aspect of the present invention includes: a substrate; an n-channel MIS transistor including: a p-type semiconductor layer formed on the substrate; a pair of n-type source/drain regions formed in the p-type semiconductor layer and isolated from each other; a first gate insulating film formed on the p-type semiconductor layer and located between the pair of n-type source/drain regions; and a first gate electrode formed on the first gate insulating. film and containing an alloy of a rare-earth metal and a metal selected from the group consisting of Ru, Pt, and Rh; and a p-channel MIS transistor including: an n-type semiconductor layer formed on the substrate; a pair of p-type source/drain regions formed in the n-type semiconductor layer and isolated from each other; a second gate insulating film formed on the n-type semiconductor layer and located between the pair of p-type source/drain regions; and a second gate electrode formed on the second gate insulating film and containing the selected metal.

A method for manufacturing a semiconductor device according to a third aspect of the present invention includes: forming a gate insulating film on a semiconductor layer; forming a film containing a metal selected from the group consisting of Ru, Pt, and Rh, the film being provided on the gate insulating film; forming a film containing a rare-earth metal on the film containing the selected metal; and forming a gate electrode containing an alloy of the selected metal and the rare-earth metal by causing solid-phase reaction between the selected metal and the rare-earth metal through heat treatment.

A method for manufacturing a semiconductor device according to a fourth aspect of the present invention includes: forming a gate insulating film on a p-type semiconductor region and an n-type semiconductor region of a semiconductor substrate; forming a Ru layer on the gate insulating film; forming a buffer layer on the Ru layer; forming a polysilicon layer on the buffer layer; forming a first gate on the n-type semiconductor region and a second gate on the p-type semiconductor region, the first gate and the second gate being formed by patterning the polysilicon layer, the buffer layer, the Ru layer, and the gate insulating film, the first gate having a stacked structure formed with the gate insulating film, the Ru layer, the buffer layer, and the polysilicon layer, the second gate having a stacked structure formed with the gate insulating film, the Ru layer, the buffer layer, and the polysilicon layer; forming a p-type impurity diffusion layer by implanting p-type impurities to the n-type semiconductor region, with the first gate serving as a mask; forming an n-type impurity diffusion layer by implanting n-type impurities to the p-type semiconductor region, with the second gate serving as a mask; selectively removing the polysilicon layer and the buffer layer from the second gate; successively forming a rare-earth metal layer and a tungsten layer on the Ru layer at the second gate; and forming an alloy layer of Ru and a rare-earth metal by causing solid-phase reaction between the Ru layer and the rare-earth metal layer at the second gate through heat treatment.

### BRIEF DESCRIPTION OF THE DRAWINGS

FIG. 1 is a cross-sectional view of a CMIS semiconductor device in accordance with a first embodiment of the present invention;

FIG. 2 schematically shows the stacked-gate structure characterizing each of the embodiments of the present invention;

FIG. 3 shows a binary phase diagram of ruthenium and yttrium;

FIG. 4 shows the principles in the material selection for each of the embodiments of the present invention;

FIG. 5 shows a binary phase diagram of ruthenium and hafnium;

FIG. 6 is a cross-sectional view illustrating a step for manufacturing the semiconductor device of the first embodiment;

FIG. 7 is a cross-sectional view illustrating a step for manufacturing the semiconductor device of the first embodiment;

FIG. 8 is a cross-sectional view illustrating a step for manufacturing the semiconductor device of the first embodiment;

FIG. 9. is a cross-sectional view illustrating a step for manufacturing the semiconductor device of the first embodiment;

FIG. 10 is a cross-sectional view illustrating a step for manufacturing the semiconductor device of the first embodiment;

FIG. 11 shows the XRD results of an experiment conducted for checking the solid-phase reaction between erbium and ruthenium;

FIG. 12 shows the XRD results of an experiment conducted for checking the solid-phase reaction between hafnium and ruthenium;

FIG. 13 illustrates the dependence of the MIS capacitor leakage characteristics on the solid-phase reaction temperature;

FIG. 14 shows the results of an experiment conducted for checking the work function of an alloy of ruthenium and a rare-earth metal on a SiO₂ insulating film;

FIG. 15 shows the results of an experiment conducted for checking the work function of an alloy of ruthenium and a rare-earth metal on a HfSiON insulating film;

FIG. 16 is a cross-sectional view of a semiconductor device in accordance with a second embodiment of the present invention;

FIG. 17 is a cross-sectional view illustrating a step for manufacturing the semiconductor device of the second embodiment;

FIG. 18 is a cross-sectional view of a semiconductor device in accordance with a third embodiment of the present invention;

FIG. 19 is a cross-sectional view illustrating a step for manufacturing the semiconductor device of the third embodiment;

FIG. 20 is a cross-sectional view illustrating a step for manufacturing the semiconductor device of the third embodiment;

FIG. 21 is a cross-sectional view illustrating a step for manufacturing the semiconductor device of the third embodiment;

FIG. 22 is a cross-sectional view illustrating a step for manufacturing the semiconductor device of the third embodiment;

FIG. 23 is a cross-sectional view illustrating a step for manufacturing the semiconductor device of the third embodiment;

FIG. 24 is a cross-sectional view of a semiconductor device in accordance with a modification of the first embodiment;

FIG. 25 is a cross-sectional view illustrating a step for manufacturing the semiconductor device of the modification of the first embodiment;

FIG. 26 is a cross-sectional view illustrating a step for manufacturing the semiconductor device of the modification of the first embodiment;

FIG. 27 is a cross-sectional view illustrating a step for manufacturing the semiconductor device of the modification of the first embodiment;

FIG. 28 is a cross-sectional view illustrating a step for manufacturing the semiconductor device of the modification of the first embodiment;

FIG. 29 is a cross-sectional view illustrating a step for manufacturing the semiconductor device of the modification of the first embodiment; and

FIG. 30 is a cross-sectional view illustrating a step for manufacturing the semiconductor device of the modification of the first embodiment.

### DESCRIPTION OF THE EMBODIMENTS

The following is a description of embodiments of the present invention, with reference to the accompanying drawings.

### First Embodiment

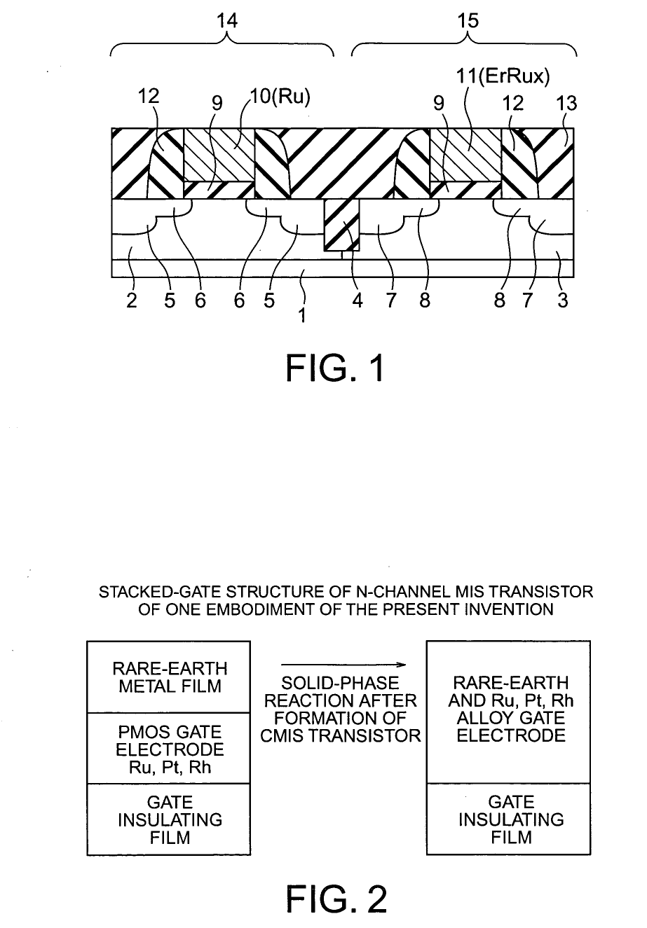

Referring to FIGS. 1 through 15, a semiconductor device in accordance with a first embodiment of the present invention is described. The semiconductor device of this embodiment is a CMIS device having the structure shown in FIG. 1.

An n-type well region 2 and a p-type well region 3 are formed in a semiconductor substrate 1. The n-type well region 2 and the p-type well region 3 are isolated from each other with a device isolating region 4 having a STI (Shallow Trench Isolation) structure.

A p-channel MIS transistor 14 is provided in the n-type well region 2. This p-channel MIS transistor 14 includes a p-type diffusion layer 5, a p-type extension layer 6, a gate insulating film 9, and a gate electrode 10 containing ruthenium. The gate insulating film 9 is provided on the n-type well region 2., and the gate electrode 10 containing ruthenium is provided on the gate insulating film 9. In this embodiment, gate sidewalls 12 made of an insulating material are provided at both side portions of the stacked structure formed with the gate insulating film 9 and the gate electrode 10.

The p-type extension layer 6 is provided in the n-type well region 2 and is located at both sides of the stacked structure formed with the gate insulating film 9 and the gate electrode 10. The p-type diffusion layer 5 is provided in the n-type well region 2 and is located at both sides of the gate sidewalls 12. The p-type diffusion layer 5 is designed to have a greater junction depth than the p-type extension layer 6 with respect to the n-type well region 2. The p-type diffusion layer 5 and the p-type extension layer 6 form the source/drain region of the p-channel MIS transistor 14.

Meanwhile, an n-channel MIS transistor 15 is provided in the p-type well region 3. The n-channel MIS transistor 15 includes an n-type diffusion layer 7, an n-type extension layer 8, the gate insulating film 9, and a gate electrode 11 containing an alloy made of ruthenium and a rare-earth metal. The gate insulating film 9 is provided on the p-type well region 3, and the gate electrode 11 is provided on the gate insulating film 9. In this embodiment, gate sidewalls 12 made of an insulating material are provided at both side portions of the stacked structure formed with the gate insulating film 9 and the gate electrode 11.

The n-type extension layer 8 is provided in the p-type well region 3 and is located at both sides of the stacked structure formed with the gate insulating film 9 and the gate electrode 11. The n-type diffusion layer 7 is provided in the p-type well region 3 and is located at both sides of the gate sidewalls 12. The n-type diffusion layer 7 is designed to have a greater junction depth than the n-type extension layer 8 with respect to the p-type well region 3. The n-type diffusion layer 7 and the n-type extension layer 8 form the source/drain region of the n-channel MIS transistor 15. Further, an interlayer insulating film 13 is formed between the p-channel MIS transistor 14 and the n-channel MIS transistor 15.

In the semiconductor device having CMIS device of this embodiment, second or third embodiments described later, the gate electrode 10 of the p-channel MIS transistor 14 contains ruthenium having a work function of approximately 5.0 eV, and the gate electrode 11 of the n-channel MIS transistor 15 contains an alloy made of ruthenium and a rare-earth metal having a work function of approximately 3.9 eV.

Each of the embodiments of the present invention is characterized by the unique manufacturing method for realizing the structure shown in FIG. 1 and the combination of the gate electrode materials essential in the manufacturing method. In each of the embodiments of the present invention, after a CMIS transistor is formed by the same manufacturing method as the conventional silicon-gate technique using ruthenium, solid-phase reaction is caused between the ruthenium in the gate electrode of the n-channel MIS transistor and a rare-earth metal, thereby forming an alloy and the desired structure (see FIG. 2). In FIG. 2, the gate electrode materials of the n-channel MIS transistor include platinum (Pt) and rhodium (Rh) as well as ruthenium (Ru). However, it is possible to use platinum (Pt) or rhodium (Rh) in place of ruthenium (Ru). The work function of Pt is 5.65 eV, and the work function of Rh is 4.98 eV.

Here, each of the embodiments of the present invention is characterized by the formation of the gate electrode of the n-channel MIS transistor through the solid-phase reaction between a rare-earth metal and ruthenium, platinum (Pt), or rhodium (Rh). Without such combinations of materials, any of the semiconductor devices in accordance with the embodiments of the present invention cannot be realized.

In each of the embodiments of the present invention, the solid-phase reaction is carried out when the CMIS transistor is almost completed. Therefore, the solid-phase reaction should be possible at a temperature of approximately 500° C. At a temperature higher than this, the device performance remarkably deteriorates due to redistribution of the channel impurities of the transistors, an increase in pn junction leakage current caused by thermal destruction of the self-aligned silicide (SALICIDE) formed on the diffusion layer, and the likes.

The metal material to be solid-phase reacted with ruthenium should decrease its work function once alloyed, and ideally exhibit a work function of approximately 4 eV. Examples of metals that might have such properties include rare-earth metals with low work functions, and metals such as hafnium and tantalum.

Each of the embodiments of the present invention is characterized by the selection of materials under the above described conditions, and the principles in the selection are as follows.

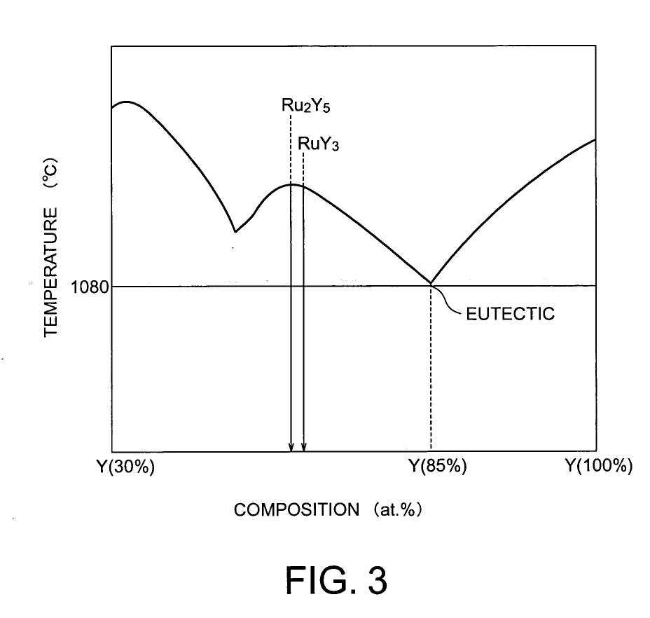

The principles in the selection based on the formation temperature restriction are now described, with ruthenium being taken as an example of a gate electrode material. When a compound is formed through solid-phase reaction between two kinds of metals, the compound phase to be formed first is known to be the closest to the lowest eutectic temperature in a phase diagram. FIG. 3 shows a phase diagram for two component system of ruthenium and yttrium, which is a rare-earth metal. The lowest eutectic temperature (1080° C.) is the point at which the concentration of yttrium is 85%, and the stable compounds closest to the lowest eutectic temperature are equivalent to the region in the vicinity of the peak of the curve in the phase diagram. More specifically, the compounds are RuY₃ and Ru₂Y₅. Those two compounds have very similar compositions, and are stabilized at almost the same temperatures. Therefore, either of the two compounds may be the first compound to be formed through solid-phase reaction. The temperature for causing solid-phase reaction is approximately half the eutectic temperature (an absolute temperature), and a RuY compound might be formed at about 400° C.

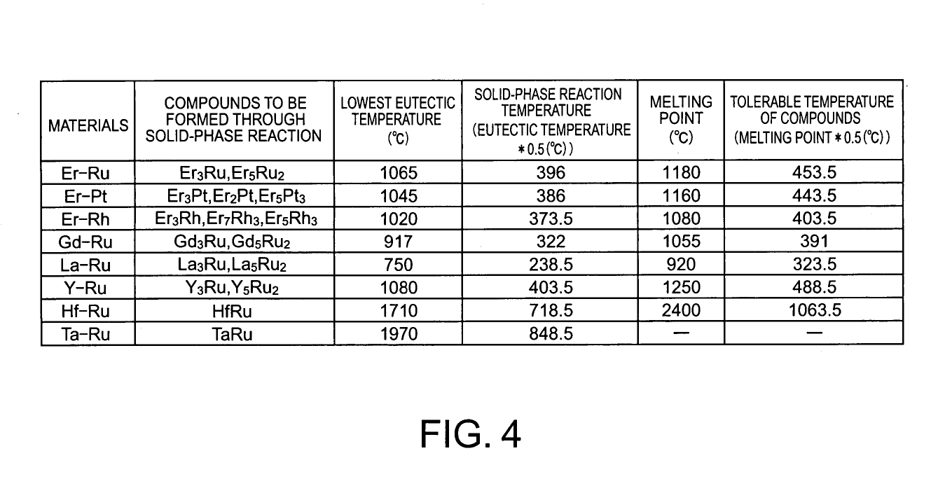

A rare-earth metal (hereinafter also referred to as RE) other than yttrium has almost the same phase diagram as that of yttrium, as can be assumed from the similarity in the chemical properties. The compounds to be first formed have the compositions of RuRE₃ and Ru₂RE₅. Although having a slightly different eutectic temperature from that of yttrium, each of those compounds should have a reaction start temperature of 250° C. to 400° C., as can be estimated from the eutectic temperature, as shown in FIG. 4. Accordingly, a rare-earth metal is a suitable material for each of the embodiments of the present invention, as it can be alloyed with ruthenium at a relatively low temperature of 500° C. after the formation of a CMIS transistor.

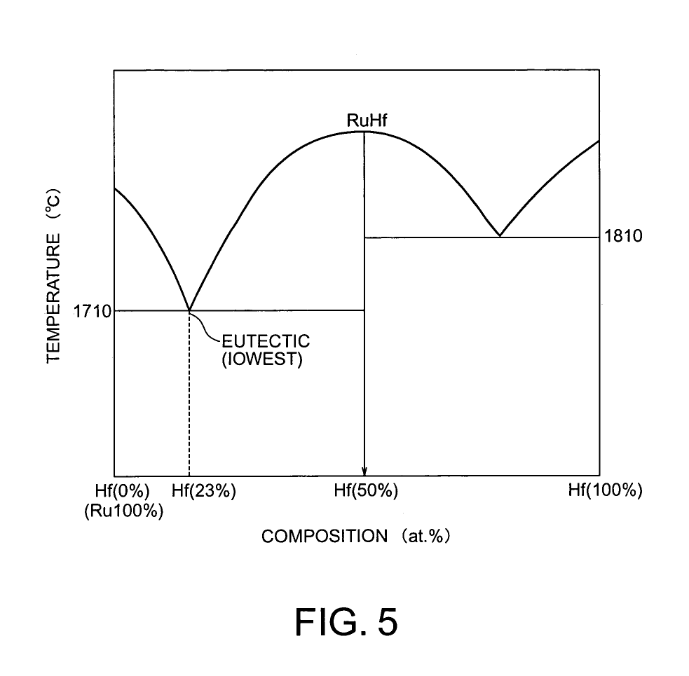

From the viewpoint of work functions, Hf (3.9 eV) or Ta (4.25 eV) is considered to be usable in an embodiment of the present invention. FIG. 5 shows a binary phase diagram of ruthenium and hafnium. The lowest eutectic temperature is 1710° C. (the concentration of hafnium being 23%), and the temperature at which reaction can be caused is approximately 720° C., which is relatively high. This does not meet the requirement of each of the embodiments of the present invention that solid-phase reaction with ruthenium is to be caused at a temperature of 500° C. or lower. Although not shown in the phase diagram, the lowest eutectic temperature of a ruthenium-tantalum material is 1970° C., and the temperature at which reaction can be started is approximately 850° C. This does not meet the requirement of each of the embodiments of the present invention.

FIG. 4 collectively shows the compositions, the eutectic temperatures, the melting points, and other properties of materials to be selected in accordance with the present invention. Since the formation temperature is restricted to 500° C. or lower, the materials that can be combined with ruthenium are limited to rare-earth metals.

Also, since each compound of a rare-earth metal and ruthenium has a RE-rich composition, the work function has a value closer to the solid-state value of the rare-earth metal, which is almost 4 eV. Such a work function value is equal to the value of n+-silicon gate conventionally used for the gate electrode each n-channel MIS transistor. In this aspect, the RE-ruthenium alloy formed through solid-phase reaction in the manufacture of the semiconductor device of each of the embodiments of the present invention contributes to improvement of the performance of the CMIS transistor.

The rare-earth metal to be used together with ruthenium as the gate electrode material of the n-channel MIS transistor in accordance with this embodiment should preferably be erbium (Er), yttrium (Y), lanthanum (La), gadolinium (Gd), or ytterbium (Yb). This is because solid-phase reaction can be caused between any of those rare-earth metals and ruthenium through low-temperature heat treatment at 500° C. or lower (see FIG. 4).

Further, the alloy of a rare-earth metal (RE) and one of ruthenium (Ru), platinum (Pt), and rhodium (Rh) as the gate electrode material of the n-channel MIS transistor in accordance with each of the embodiments of the present invention should preferably exhibit a value between 2.5 and 3 as the ratio of the composition concentration (atomic %) of the rare-earth metal in relation to one of ruthenium (Ru), platinum (Pt), and Rhodium (Rh) (=RE concentration (atomic %)/(concentration (atomic %) of metal selected from Ru, Pt, and Rh). This is because the compound formed through the solid-phase reaction has the composition ratio restricted to this range, and within this range, each gate electrode has a stable structure from the viewpoint of thermodynamics.

Also, the alloy of a rare-earth metal and one of ruthenium (Rh), platinum (Pt), and rhodium (Rh) as the gate electrode material of the n-channel MIS transistor in accordance with each of the embodiments of the present invention has a RE-rich composition as described above. This has the preferred effect of reducing the work function of the gate electrode of each n-channel MIS transistor.

Here, the region of the gate electrode having the composition concentration ratio of 2.5 to 3 should preferably be located on the side of the gate insulating film, and the film thickness of this region should be 1.5 nm or larger. Only when the film thickness exhibits this value or higher in this position, can the low work function of the gate electrode function to lower the threshold voltage of the n-channel MOS transistor.

In each of the embodiments of the present invention, the source/drain regions can be formed of a metal or a metal-silicide of Ni or Co etc.

(Manufacturing Method) Next, the method for manufacturing the semiconductor device of the first embodiment is described.

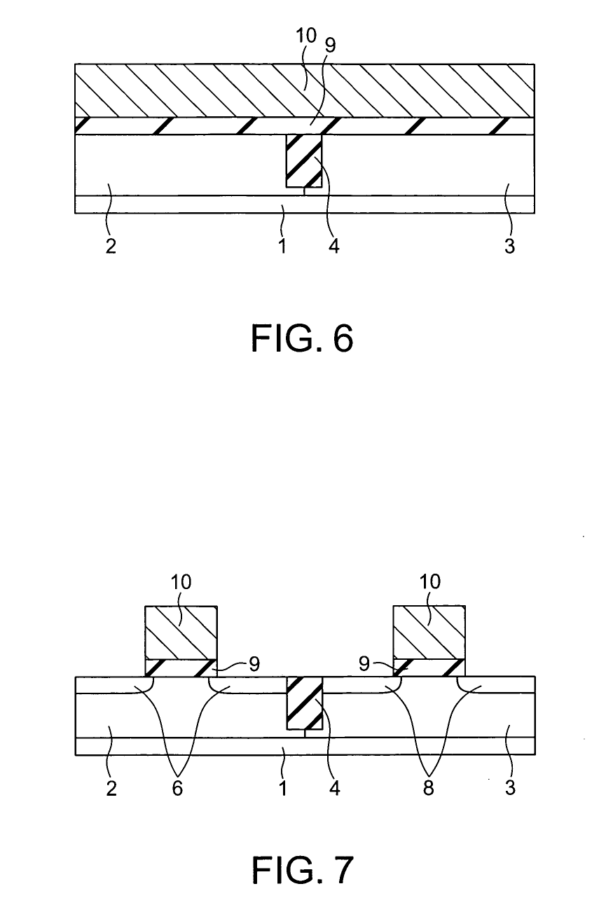

FIGS. 6 through 10 illustrate the procedures for manufacturing the semiconductor device of this embodiment. By this manufacturing method, the alloy RuEr₃ is used for the gate electrode 11 containing an alloy of ruthenium and a rare-earth metal.

As shown in FIG. 6, the n-type well region 2 and the p-type well region 3 isolated from each other with the device isolating region 4 having a STI structure are formed in the semiconductor substrate 1. The gate insulating film 9 and the gate electrode film 10 containing ruthenium are deposited on the semiconductor substrate 10. Examples of gate insulating materials include silicon oxide film, high-permittivity (high-k) insulating film (an insulating film material exhibiting high permittivity with respect to silicon oxide film), and a mixture of those materials. The high-permittivity insulating film may be made of a metal silicate or a metal aluminate of Hf, Zr, La, or the like, or an insulating film having such a material supplied with nitrogen, or an insulating film made of Si₃N₄, Al₂O₃, Ta₂O₅, TiO₂, La₂O₃, CeO₂, ZrO₂, HfO₂, SrTiO₃, Pr₂O₃, or the like. The silicon oxide film may be made of SiO₂, while the high-permittivity insulating film is made of SiOₓN_{y}, HfO₂, HfOₓN_{y}, HfSiₓO_{y}, HfSiₓO_{y}N_{z}, HfAlₓO_{y}, HfAlₓO_{y}N_{z}, LaHfₓO_{y}, LaAlₓO_{y}, Al₂O₃, ZrO₂, ZrSiₓO_{y}, ZrSiₓO_{y}N_{z}, or the like. Here, a thermal oxide SiO₂ film of 2 nm in thickness or a HfSiON film (the composition ratio (=Hf/(Hf+Si)) being approximately 0.5, the nitrogen concentration being 20 atomic %) of 3 nm in thickness is deposited by MOCVD (Metal Organic Chemical Vapor Deposition), for example. The deposition method may be ALD (Atomic Layer Deposition), MBE (Molecular Beam Epitaxy), or PVD (Physical Vapor Deposition), instead of MOCVD. The gate electrode 10 containing ruthenium may be formed by a conventional technique such as CVD or PVD. The film thickness of the gate electrode 10 containing ruthenium is 50 nm in this embodiment.

As shown in FIG. 7, patterning is performed for the gate electrodes 10 containing ruthenium on the n-type well region 2 and the p-type well region 3. In this embodiment, the patterning is performed by oxygen RIE (Reactive Ion Etching). The portions of the gate insulating layer 9 not covered with the gate electrodes 10 are then removed by wet etching, for example. Ruthenium is highly resistant to chemicals, and even if etching with a fluorinated acid solution or the like is performed on the gate insulating layer 9 made of SiO₂ or HfSiON, the ruthenium is not etched by the chemical. With the gate electrodes 10 serving as masks, ion implantation is performed in a self-aligning fashion on the n-type well region 2 and the p-type well region 3 in separate procedures, so as to form the extension layers 6 and 8 (see FIG. 7).

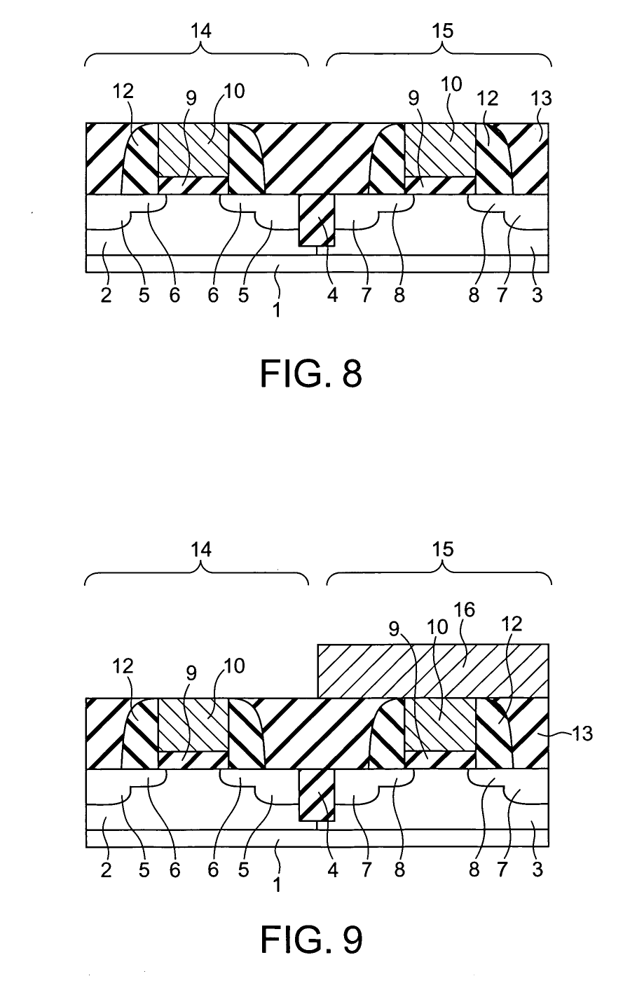

As shown in FIG. 8, the gate sidewalls 12 made of an insulating material are then formed at side portions of each gate electrode 10. With the gate sidewalls 12 and the gate electrodes 10 serving as masks, ion implantation is further performed on the n-type well region 2 and the p-type well region 3 independently of each other, so as to form the diffusion layer 5 and the diffusion layer 7. The interlayer insulating film 13 is then formed on the entire surface of the substrate 1, and polishing such as CMP (Chemical Mechanical Planarization) for flattening the surface is performed so as to obtain the structure shown in FIG. 8. Through this series of procedures, ruthenium (Ru) is very stable both thermally and chemically. Accordingly, most of the procedures can be carried out in the same manner as in a case of a conventional silicon gate. However, the only problem with ruthenium is the high reactivity with oxygen. Therefore, the post oxidization process to be carried out for a conventional silicon gate needs to be skipped.

As shown in FIG. 9, an erbium layer 16 is deposited only on the p-type well region 3. The film thickness of the erbium layer 16 is set at 200 nm, which is greater than the film thickness of the gate electrode 10 containing ruthenium, so that the ultimate ruthenium-erbium alloy can certainly have an erbium-rich composition.

A tungsten layer is further deposited on the erbium layer 16, so as to restrain oxidization of the erbium in later procedures. This tungsten layer also serves to soften the thin-film agglomeration due to the solid-phase reaction between erbium and ruthenium, and ultimately reduces damage to the gate insulating film.

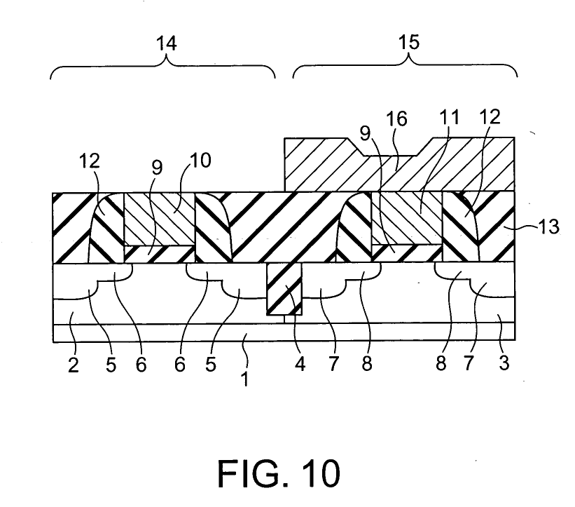

Heat treatment is then carried out at a temperature of 500° C. or lower, so as to cause solid-phase reaction between the erbium layer 16 on the p-type well region 3 and the gate electrode 10 containing ruthenium. Thus, the gate electrode 11 made of a ruthenium-erbium alloy is formed (see FIG. 10).

The unreacted erbium is then removed through treatment with a combined chemical solution of sulfuric acid and hydrogen peroxide, so as to flatten the device surface. Thus, the semiconductor device of this embodiment illustrated in FIG. 1 can be obtained.

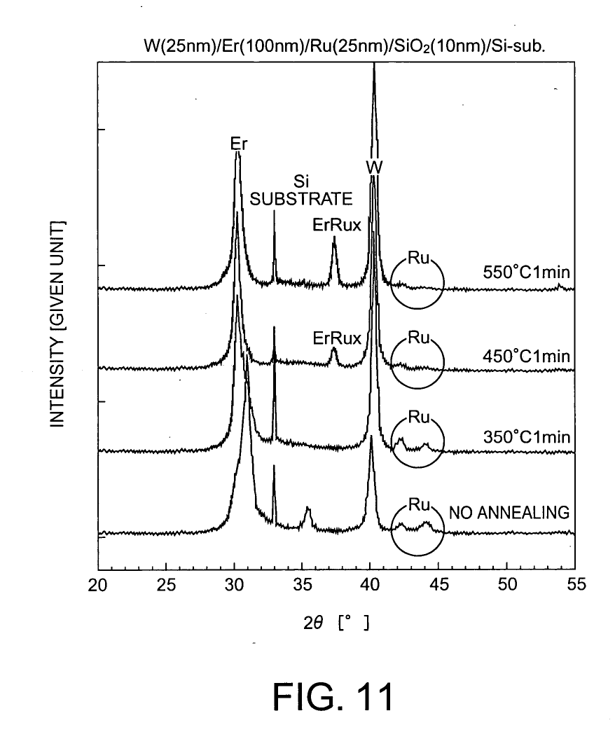

FIG. 11 shows the results of a preliminary experiment that was conducted to check the solid-phase reaction between ruthenium and erbium. Heat treatment was first carried out for a stacked structure of tungsten (25 nm)/erbium (100 nm)/ruthenium (25 nm)/SiO₂ (10 nm)/Si at temperatures of 350° C. to 550° C. for one minute, and the changes in the crystalline structure were observed with XRD (X-ray diffractometry). The numbers shown in the brackets represent the film thicknesses. In FIG. 11, the abscissa axis indicates the diffraction angle 20 of diffracted X-rays, and the ordinate axis indicates the crystalline diffraction intensity. As can be seen from FIG. 11, no changes were observed in the film crystalline structure when the reaction temperature was 350° C. At 450° C., however, the peak intensity of ruthenium weakened, and the diffraction peak of ErRuₓ appeared. When the reaction temperature was increased to 550° C., the peak intensity of ruthenium became even lower, and the peak intensity of ErRuₓ became even higher. From this result, it became apparent that solid-phase reaction was easier at a higher temperature. This result is the same as the prediction on the basis of the eutectic of Er-Ru shown in FIG. 4 that reaction starts at approximately 400° C.

Although the results described above are the results of the preliminary experiment for checking the reaction processes between erbium and ruthenium, it is also possible to confirm the formation of the alloy of erbium and ruthenium in the gate electrode in accordance with this embodiment, after the completion of a CMOS transistor. More specifically, after the CMOS device shown in FIG. 1 is completed, the sample for observing the cross sectional TEM (Transmission Electron Microscopy) is wiped off the LSI wafer by a conventional pickup method or the like. Once the structure shown in FIG. 1 is confirmed through the section TEM, electron beams are emitted onto the gate electrode made of ErRux. The electron beam diffraction pattern at the gate electrode is analyzed, so that the structure of the crystals (Er₅Ru₂ or Er₃Ru) forming the gate electrode can be identified. In a case where the film thickness of the gate electrode made of ErRux is as thick as 100 nm as in this embodiment, electron beams are defocused so as to increase the diffraction intensity and the crystal identifying accuracy. Even if the film thickness of the electrode layer made of ErRux has a nanometer order size, the crystals constituting the minute region can be identified in principle by focusing electrons beams to the same size or an even smaller size, though the diffraction intensity decreases.

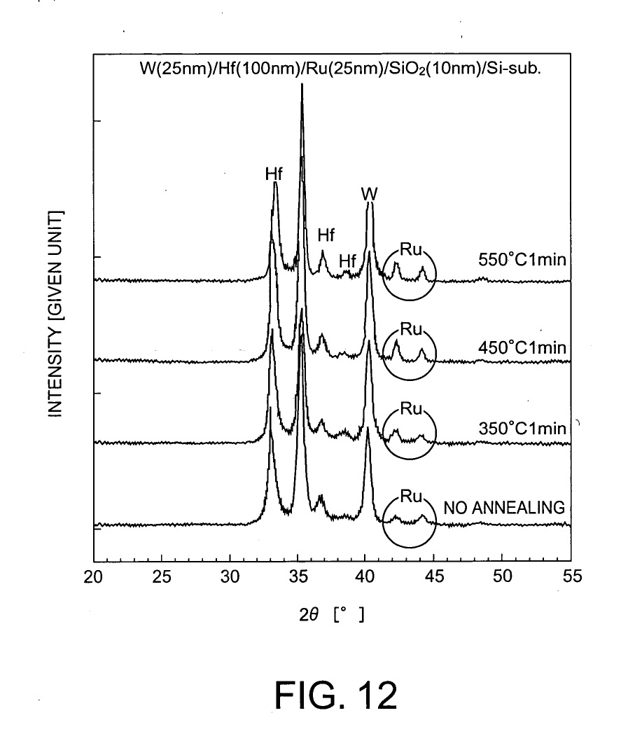

FIG. 12 shows the results of a preliminary experiment that was conducted to observe the changes in the crystalline structure with XRD after heat treatment was first carried out for a stacked structure of tungsten (25 nm)/hafnium (100 nm)/ruthenium (25 nm)/SiO₂ (10 nm)/Si at temperatures of 350° C. to 550° C. for one minute. As can be seen from FIG. 12, solid-phase reaction between the ruthenium and hafnium was not caused at the temperatures used in this heat treatment, and any change was not observed in the XRD diffraction spectrum. This is the same as the prediction on the basis of the result shown in FIG. 4 that a temperature of approximately 720° C. is necessary to cause reaction between Hf and Ru.

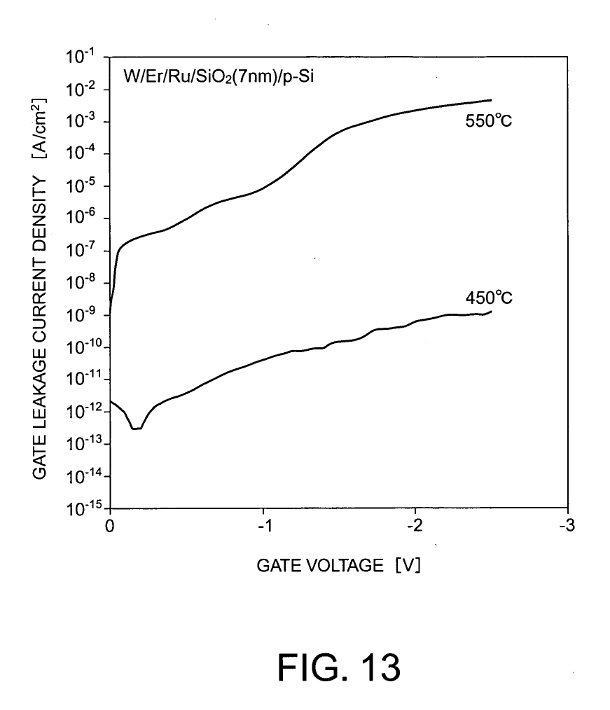

FIG. 13 shows the current-voltage characteristics of a MIS capacitor having heat treatment carried out on a stacked structure of tungsten/erbium/ruthenium/SiO₂ (7 nm)/p-type Si. The gate leakage current remained low at a heat treatment temperature of 450° C., but a large increase in gate leakage was caused at a heat treatment temperature of 550° C. This implies that the erbium that reacted with the ruthenium chemically reacted with the gate insulating film, and short-circuiting was electrically caused in the MIS capacitor.

A temperature higher than a certain value is necessary to trigger the solid-phase reaction between ruthenium and a rare-earth metal in this embodiment. However, there are upper and lower limits to the temperature, because the gate insulating film is electrically short-circuited at a temperature higher than a certain temperature. The lower limit depends on the material employed for the gate electrode (see FIG. 4), and are 200° C. to 400° C. On the other hand, the upper limit is 500° C. at a maximum, with the reactivity between a rare-earth metal and the gate insulating film being taken into consideration.

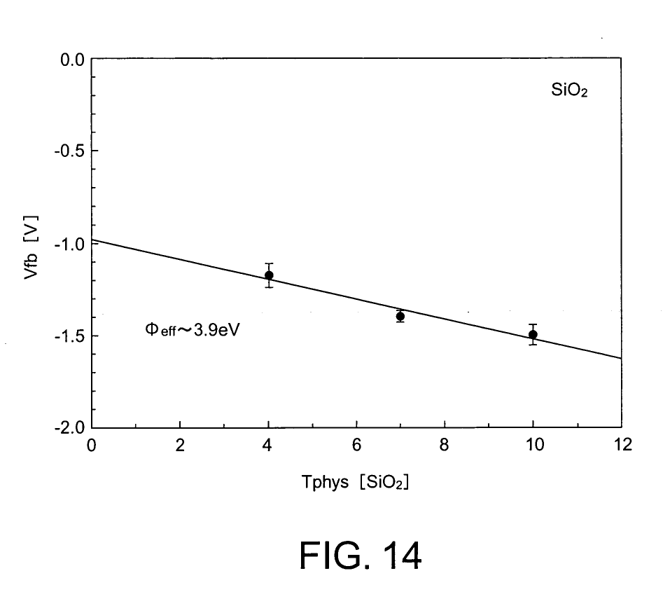

FIG. 14 shows the results of an experiment carried out to check the work function (Φeff) of the gate electrode made of an ErRu alloy in a case where SiO₂ was used as the material for the gate insulating film. In FIG. 14, the abscissa axis indicates the physical film thickness Tphys of the SiO₂ film, and the ordinate axis indicates the flat band voltage. In this experiment, the film thickness of the SiO₂ film was varied when the value of the work function was checked. As shown in FIG. 14, this experiment made it apparent that the work function of the gate electrode made of an ErRu alloy was approximately 3.9 eV. This is clearly closer to the properties of erbium, with the work function of ruthenium (5.0 eV) and the work function of erbium (3.5 eV) being taken into consideration. This result also represents the characteristics of this embodiment in which an erbium-rich ErRu alloy can be automatically formed through solid-phase reaction.

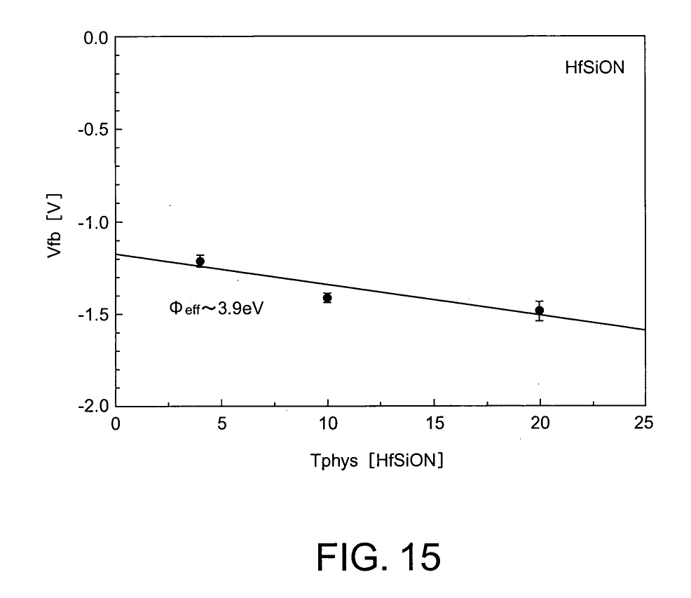

FIG. 15 shows the results of an experiment carried out to check the work function of the gate electrode made of an ErRu alloy in a case where HfSiON was used as the material for the gate insulating film. In this experiment, the film thickness of the HfSiON film was varied when the value of the work function was checked. As shown in FIG. 15, this experiment made it apparent that the work function of the gate electrode made of an ErRu alloy was approximately 3.9 eV. In general, the work function of the metal gate formed on a high-permittivity insulating film such as a HfSiON film is slightly higher than in a case where the metal gate is formed on an insulating film made of SiO₂. However, this does not apply to the case of the Er-Ru alloy of the gate electrode 11 in this embodiment, and the value of the work function of the gate electrode 11 does not depend on the base film. The increase in the work function of the metal gate formed on a high-permittivity insulating film is considered to be caused by the microscopic reaction between the metal gate and the high-permittivity insulating film. Therefore, the ErRu alloy of the gate electrode 11 of this embodiment is a suitable material that does not react with a high-permittivity insulating film.

In this embodiment, the same self-aligning process as the process used for a conventional polysilicon gate electrode is used for the metal gate electrode. The most suitable material for the self-aligning process among the above described gate electrode materials is ruthenium, which has the highest heat resistance.

(Modification)

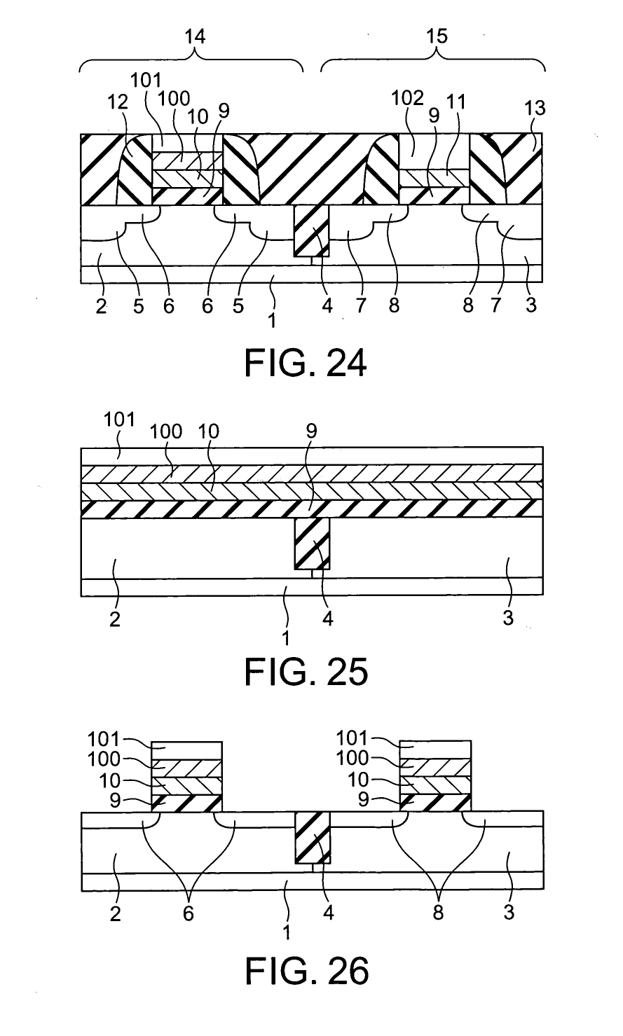

Referring now to FIGS. 24 through 30, a semiconductor device in accordance with a modification of this embodiment is described. As shown in FIG. 24, the semiconductor device of this modification differs from the semiconductor device of the first embodiment shown in FIG. 1 in that the gate electrode on the n-type well region 2 has a three-layer stacked structure of a ruthenium layer 10, a titanium nitride layer 100, and a polysilicon layer 101, and the gate electrode on the p-type well region 3 has a stacked structure of an alloy layer 11 of ruthenium and a rare-earth metal and a tungsten layer 102.

Referring now to FIGS. 25 through 30, the method for manufacturing the semiconductor device of this modification is described.

After the n-type well region 2 and the p-type well region 3 that are isolated from each other with the device isolating region 4 having a STI structure are formed on the semiconductor substrate 1, the structure shown in FIG. 25 is formed by depositing the gate insulating film 9, the gate electrode layer 10 containing ruthenium, the TiN layer 100, and the polysilicon layer 101 on the semiconductor substrate 1. The material and the film thickness of the gate insulating film 9 are the same as those in the first embodiment. The ruthenium layer 10 can be deposited by PVD or CVD, and the film thickness of the ruthenium layer 10 in this modification is 10 nm. The TiN layer 100 is a buffer layer between the ruthenium layer 10 and the polysilicon layer 101 deposited on the TiN layer 100. The TiN layer 100 functions to increase the adhesiveness between the polysilicon layer 101 and the ruthenium layer 10 and prevent reaction between the polysilicon layer 101 and the ruthenium layer 10. Any other material may be employed, instead of TiN, as long as it has the above described functions. For example, TaN, TaSiN, or TiSiN may be employed. In this modification, the TiN layer 100 of 10 nm in film thickness is formed by CVD. The polysilicon layer 101 having a film thickness of 80 nm is deposited on the TiN layer 100 by the conventional CVD.

As shown in FIG. 26, patterning is performed on the stacked film formed with the ruthenium layer 10, the TiN layer 100, and the polysilicon layer 101 on the n-type well region 2 and the p-type well region 3, so as to form gate electrodes each having a stacked structure. In this embodiment, after patterning is performed on the polysilicon layer 101 and the TiN layer 100 by RIE using a mixed gas of HBr and a chlorine-based gas, etching is performed on the ruthenium layer 10 by oxygen RIE. The portions of the gate insulating film 9 that are not covered with the gate electrodes having stacked structures are removed by wet etching or the like. The ruthenium layer 10, the TiN layer 100, and the polysilicon layer 101 are highly resistant to chemicals. For example, even if etching with a fluorinated acid solution is performed on the gate insulating film 9 made of SiO₂ or HfSiON, the gate electrode is not eroded with the chemicals. With the gate electrodes having the stacked structures serving as masks, ion implantation is performed in a self-aligning fashion in the n-type well region 2 and the p-type well region 3 in separate procedures from each other, so as to form the extension layers 6 and 8 (see FIG. 26).

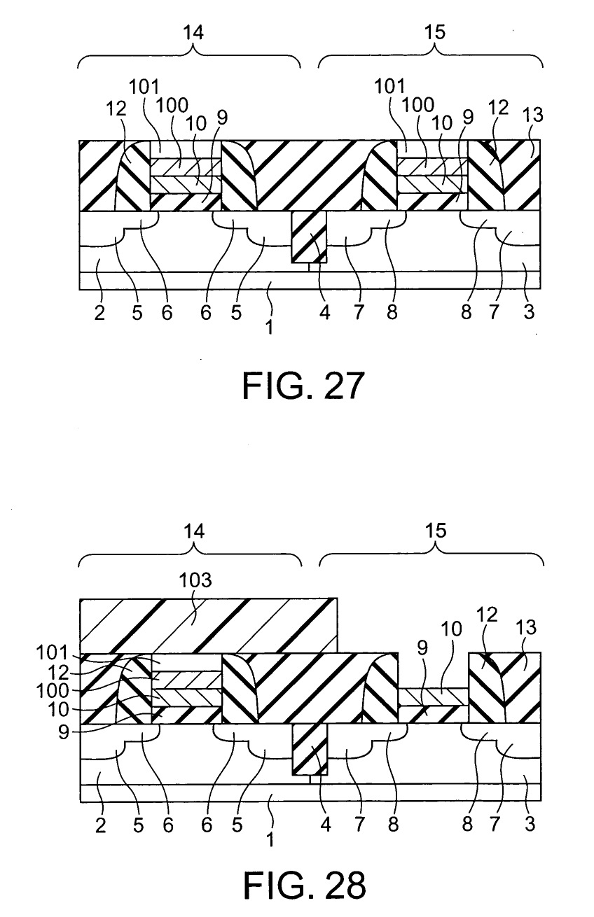

As shown in FIG. 27, the gate sidewalls 12 made of an insulating material are formed at side portions of each gate electrode having a stacked structure. With the gate. sidewalls 12 and the gate electrodes of the stacked structures serving as masks, ion implantation is performed in the n-type well region 2 and the p-type well region 3 separately from each other, so as to form the p-type diffusion layer 5 and the n-type diffusion layer 7. The interlayer insulating film 13 is then deposited on the entire surface of the substrate 1, and polishing (such as CMP) is performed to flatten the surface.

Throughout this series of steps, most of the steps can be carried out in the same manner as the conventional silicon gate processes, since ruthenium and TiN are very stable both thermally and chemically, and the ruthenium layer and the TiN layer are covered with polysilicon, which is also a very stable material. More specifically, the gate surface is mostly a polysilicon layer at the time of gate processing in this modification, and the processed shape of each gate electrode is decided by the processing accuracy of the polysilicon. Therefore, the shapes of the gate electrodes of this modification have almost the same quality as those obtained by the conventional method, and the gate electrodes of this modification are formed by almost the same steps as those by the conventional method. Also, since only a small portion of ruthenium, which is easily affected by heat treatment in an oxygen atmosphere, is exposed through the side faces of the gate electrodes, the post oxidization process after the gate electrode formation is easier than in the first embodiment. This modification has the above described advantages.

A mask layer 103, such as a resist layer, is then formed only on the n-type well region 2. The polysilicon layer 101 on the p-type well region 3 is then removed by dry etching with CF₄ and oxygen, for example, and the TiN layer 100 on the p-type well region 3 is removed by wet etching with a hydrogen peroxide solution. Thus, the structure shown in FIG. 28 is obtained.

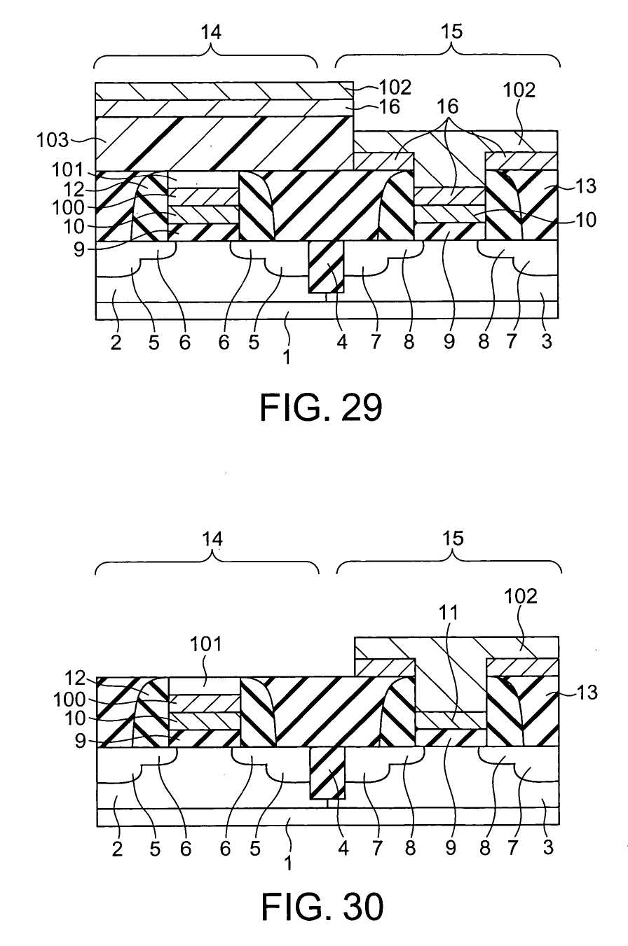

The Er layer 16 and the tungsten layer 102 are successively deposited on the structure shown in FIG. 28, thereby forming the structure shown in FIG. 29. These layers can be deposited by PVD and CVD. The film thickness of the Er layer 16 is 30 nm, and the film thickness of the tungsten layer 102 is 50 nm.

The mask layer 103 is removed from the structure shown in FIG. 29, and the metal layers 16 and 102 existing on the mask layer 103 are lifted off. Heat treatment is then carried out under the same condition as in the first embodiment, or heat treatment is carried out at approximately 500° C., so as to cause solid-phase reaction between the ruthenium layer 10 and the Er layer 16 on the p-type well region 3. Thus, the structure shown in FIG. 30 is obtained.

The device surface is then flattened so as to obtain the semiconductor device illustrated in FIG. 24. Since each gate electrode has a stacked structure in this embodiment, the manufacturing steps are slightly more complicated. Also, since the polysilicon layer is used as a part of the gate electrodes, the gate resistance becomes slightly higher. Despite these drawbacks, this modification has a great advantage over the first embodiment in the higher consistency with the conventional polysilicon gate process, as a CMOS transistor having the uppermost portion of each gate electrode covered with polysilicon can be formed in this embodiment.

As described above, in accordance with this embodiment, a CMIS device having gate electrodes that have low resistance and high heat resistance and are free of depletion problems can be obtained. Also, this embodiment can prevent an increase in the number of procedures for manufacturing the CMIS device in relation to the number of steps in the conventional method, and make complicated processes unnecessary.

### Second Embodiment

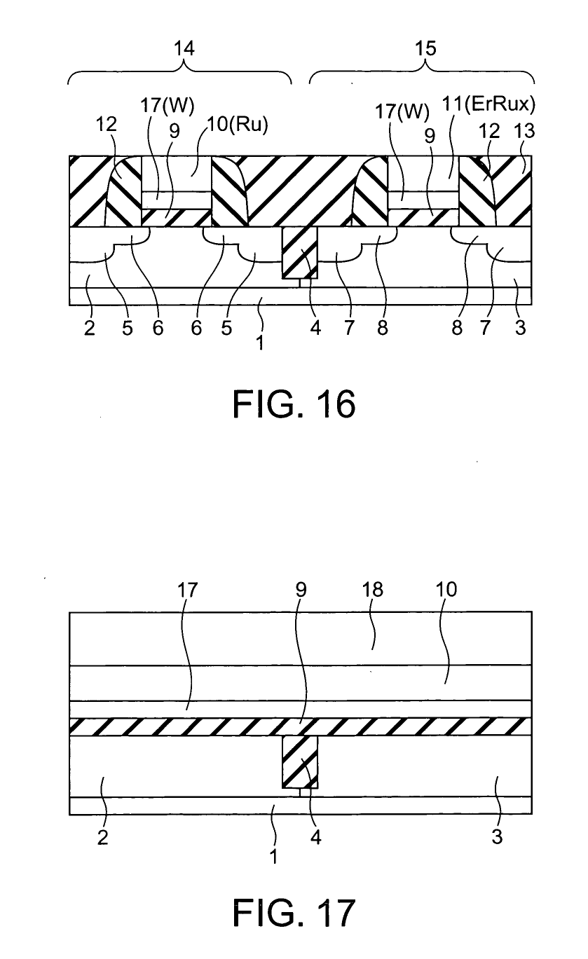

FIG. 16 is a cross-sectional view of a semiconductor device in accordance with a second embodiment of the present invention. The semiconductor device of this embodiment is a CMIS device that has the same structure as the CMIS device of the first embodiment shown in FIG. 1, except that a tungsten layer 17 is provided between the gate insulating film 9 and the gate electrodes 10 and 11.

By the method for manufacturing the CMIS device of this embodiment, a gate insulating film 9 and a gate electrode 10 containing ruthenium are formed in the same manner as in the first embodiment, as shown in FIG. 17. A tungsten layer 18 is deposited on the gate electrode 10, and heat treatment at temperatures between 800° C. and 950° C. is carried out to form the tungsten layer 17 at the interface between the gate insulating film 9 and the gate electrode 10. After the tungsten layer 18 is removed, the procedures in accordance with the first embodiment as shown in FIGS. 7 through 10 are carried out to obtain the CMIS device illustrated in FIG. 16.

This embodiment is characterized by the tungsten layer 17 that stabilizes the interface between the insulating film 9 and the gate electrode 11 made of an alloy of ruthenium and a rare-earth metal in the n-channel MIS transistor 15 shown in FIG. 16. Unlike a rare-earth metal and ruthenium, tungsten is not likely to form a stable oxide from the viewpoint of thermodynamics, and accordingly, stabilizes the interface with the gate insulating film.

The tungsten layer 17 is formed by segregating the grain boundary of Ru at the interface with the gate insulating film 9 through high-speed diffusion in the step shown in FIG. 17. The thickness of the tungsten layer 17 is as thin as a layer formed with several atoms, 1.5 nm at a maximum. Accordingly, the tungsten layer 17 does not exhibit a work function with a value that should be inherent to tungsten, while functioning to stabilize the interface. On the other hand, the work function of the gate electrode 11 made of an alloy of ruthenium and a rare-earth metal is exercised.

As in the first embodiment, an increase in the number of manufacturing steps can be prevented as much as possible in this embodiment, and a semiconductor device having a CMIS device with metal gates can be obtained under less complicated conditions.

### Third Embodiment

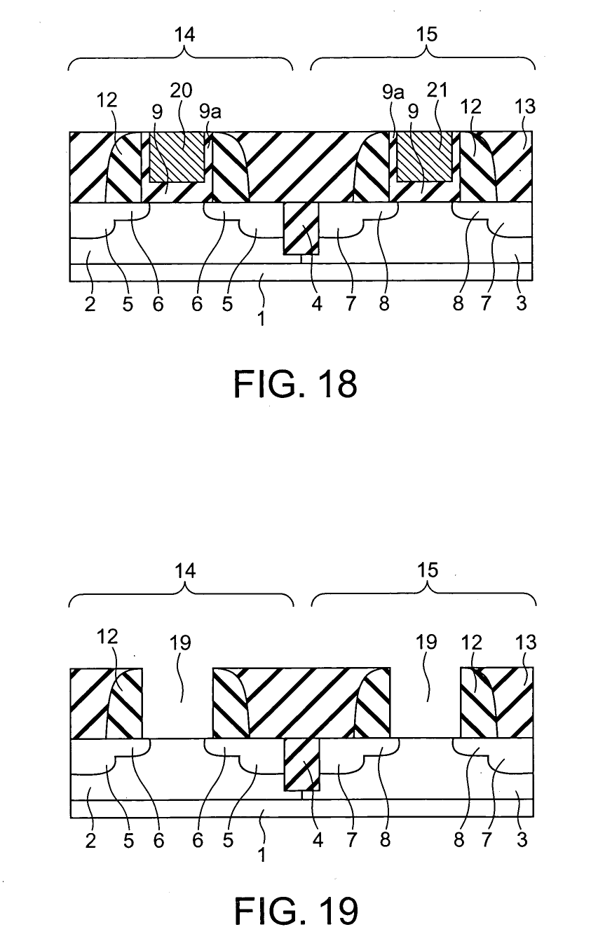

FIG. 18 is a cross-sectional view of a semiconductor device in accordance with a third embodiment of the present invention. The semiconductor device of this embodiment is a CMIS device that differs from the CMIS device of the first embodiment shown in FIG. 1, in that the gate electrode 10 containing ruthenium is replaced with a gate electrode 20 containing platinum, the gate electrode 11 made of an alloy of ruthenium and a rare-earth metal is replaced with a gate electrode 21 made of an alloy of platinum and a rare-earth metal, and an insulating film 9a is provided between the gate sidewalls 12 and the gate electrodes 20 and 21.

The semiconductor device of this embodiment is formed by a replacement gate process. Referring now to FIGS. 19 through 23, the method for manufacturing the semiconductor device of this embodiment is described.

As shown in FIG. 19, the n-type well region 2 and the p-type well region 3 that are isolated from each other with the device isolating region 4 having a STI structure are formed on the semiconductor substrate 1. A dummy gate (not shown) is formed in each of the n-type well region 2 and the p-type well region 3. With the dummy gates serving as masks, p-type impurities are implanted to the n-type well region 2, so as to form the p-type extension layer 6, and n-type impurities are implanted to the n-type well region 3, so as to form the n-type extension layer 8. The gate sidewalls 12 are then formed at side portions of the dummy gates. With the dummy gates and the gate sidewalls 12 serving as masks, p-type impurities are implanted to the n-type well region 2, so as to form the p-type diffusion layer 5, and n-type impurities are implanted to the p-type well region 3, so as to form the n-type diffusion layer 7. The interlayer insulating film 13 is then deposited, and the surface of the interlayer insulating film 13 is flattened. The dummy gates are then removed, so as to obtain the structure shown in FIG. 19. As can be seen from FIG. 19, after the dummy gates are removed, grooves 19 are formed. A SALICIDE layer may be formed on each of the diffusion layers 5 and 7.

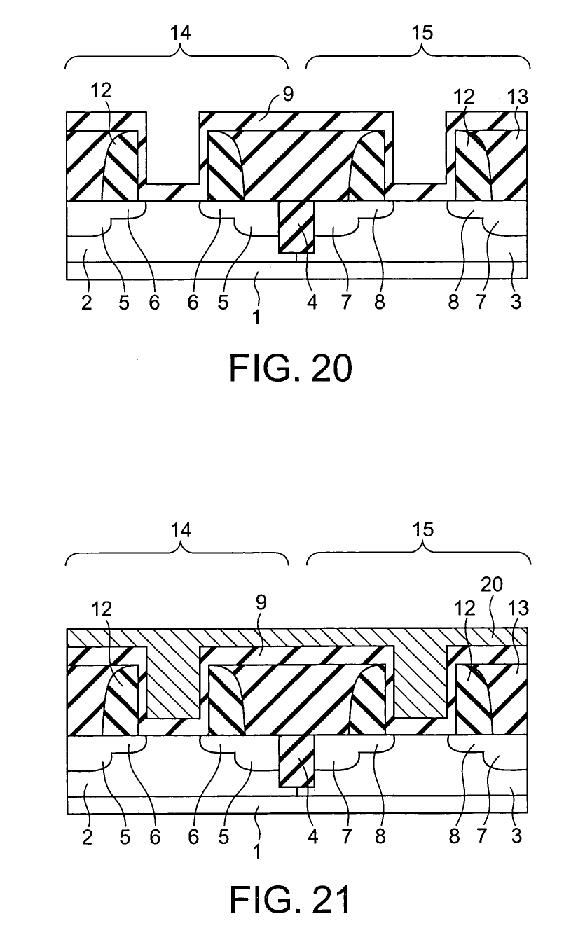

The gate insulating film 9 is then deposited, as shown in FIG. 20. Here, a hafnium silicate film with a thickness of 3 nm is deposited by ALD. The deposition method may be MOCVD or the like, as long as an insulating film can be formed on the bottom face of each of the grooves 19 after the dummy gates are removed. The material of the gate insulating film 9 may be HfSiON having nitrogen added to hafnium silicate, or may be any other material that does not limit the effects of this embodiment.

The gate electrode 20 containing platinum of approximately 100 nm in thickness is then deposited on the gate insulating film 9, as shown in FIG. 21. Although the self-aligning process is employed in the first and second embodiments, the replacement gate process is used in this embodiment. Since the source/drain regions of each transistor have already been formed, the process of forming the gate electrode should exhibit heat resistance to temperatures between 400° C. and 500° C., and rhodium may be employed as well as platinum. It is of course possible to employ ruthenium, which has high heat resistance, for the gate electrode.

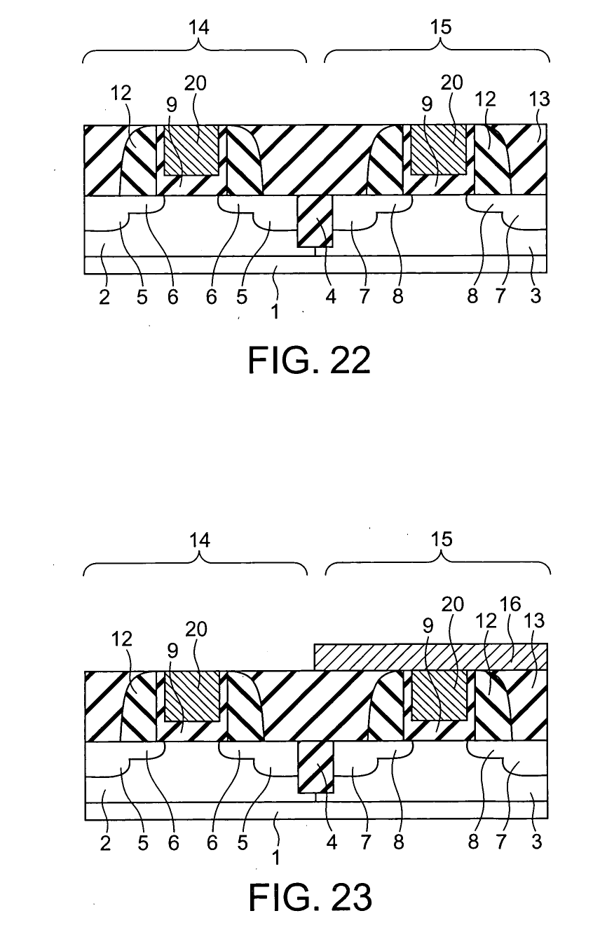

The device structure is then flattened by the conventional CMP, so as to obtain the structure shown in FIG. 22.

The erbium layer 16 with a thickness of approximately 300 nm is then formed only on the p-type well region 3, so as to obtain the structure shown in FIG. 23. Instead of erbium, the above described rare-earth metal may be selected. Reaction is caused between the gate electrode 20 containing platinum and the erbium layer 16, thereby forming an alloy of platinum and erbium. The unreacted erbium is removed with a mixed solution of sulfuric acid and hydrogen peroxide. Thus, the structure shown in FIG. 18 is obtained.

In a modification of this embodiment, ruthenium (Ru) or rhodium (Rh) is used, instead of platinum (Pt), and a p-channel MIS transistor and an n-channel MIS transistor are formed by the replacement gate process. Solid-phase reaction is then caused only between the gate electrode of the n-channel MIS transistor and a rare-earth metal, so as to form a gate electrode that is made of an alloy of the rare-earth metal and Ru or Rh, and has a work function of approximately 3.9 eV. Since the replacement gate process involving low temperatures is used in this modification, the consistency with the self-aligning process with respect to the gate electrode of the p-channel MIS transistor, or the requirement of high-temperature heat treatment at approximately 1000° C., does not need to be taken into consideration. With the conditions for the solid-phase reaction at a low temperature of about 500° C. and the formation of a compound with a high proportion of rare-earth metal and a low work function being taken into account, platinum or rhodium can be used as well as ruthenium, as shown in FIG. 4. Like a gate electrode containing ruthenium (Ru) or rhodium (Rh), the gate electrode made of an alloy of platinum (Pt) and a rare-earth metal has a work function of approximately 3.9 eV.

In accordance with this embodiment, an increase in the number of manufacturing steps can also be prevented as much as possible, and a semiconductor device having a CMIS device with metal gates can be obtained under less complicated conditions.

As described above, in accordance with each of the embodiments of the present invention, a semiconductor device having MIS transistors with metal gates and a method for manufacturing the semiconductor device can be provided, while increases in the number of manufacturing procedures and the difficulties in the manufacturing conditions can be prevented as much as possible.

The present invention is not limited to the above embodiments, but modifications may be made to the components without departing from the scope of the invention. Also, various changes made to the invention by combining the components disclosed in the above embodiments. For example, some components may be removed from the structures disclosed in the above embodiments, or components of different embodiments may be combined.

What is claimed is:

1. A semiconductor device comprising
a substrate; and
an n-channel MIS transistor including:
a p-type semiconductor layer formed on the substrate;
a pair of n-type source/drain regions formed in the p-type semiconductor layer and isolated from each other;
a first gate insulating film formed on the p-type semiconductor layer and located between the pair of n-type source/drain regions; and
a first gate electrode formed on the first gate insulating film and containing an alloy of a rare-earth metal and a metal selected from the group consisting of Ru, Pt, and Rh.

2. The semiconductor device according to claim 1, wherein the n-channel MIS transistor has a first tungsten layer provided between the first gate insulating film and the first gate electrode.

3. The semiconductor device according to claim 1, wherein a ratio of the composition concentration (atomic %) of the rare-earth metal to the selected metal is in the range of 2.5 to 3.

4. The semiconductor device according to claim 1, wherein a region in which a ratio of the composition concentration (atomic %) of the rare-earth metal to the selected metal is in the range of 2.5 to 3 is located at a portion of the first gate electrode on the side of the first gate insulating film, and has a film thickness of 1.5 nm or larger.

5. The semiconductor device according to claim 1, wherein the rare-earth metal is one of Er, Y, La, Gd, and Yb.

6. The semiconductor device according to claim 1, wherein the alloy of the selected metal and the rare-earth metal is RuEr₃ alloy.

7. The semiconductor device according to claim 1, wherein an insulating film of the same material as the first gate insulating film is formed on side faces of the first gate electrode.

8. The semiconductor device according to claim 1, wherein the first gate insulating film is one of SiOₓN_{y}, HfO₂, HfOₓN_{y}, HfSiₓO_{y}, HfSiₓO_{y}N_{z}, HfAlₓO_{y}, HfAlₓO_{y}N_{z}, LaHfₓO_{y}, LaAlₓO_{y}, Al₂O₃, ZrO₂, ZrSiₓO_{y}, and ZrSiₓO_{y}N_{z}.

9. A semiconductor device comprising:
a substrate;
an n-channel MIS transistor including: a p-type semiconductor layer formed on the substrate; a pair of n-type source/drain regions formed in the p-type semiconductor layer and isolated from each other; a first gate insulating film formed on the p-type semiconductor layer and located between the pair of n-type source/drain regions; and a first gate electrode formed on the first gate insulating film and containing an alloy of a rare-earth metal and a metal selected from the group consisting of Ru, Pt, and Rh; and
a p-channel MIS transistor including: an n-type semiconductor layer formed on the substrate; a pair of p-type source/drain regions formed in the n-type semiconductor layer and isolated from each other; a second gate insulating film formed on the n-type semiconductor layer and located between the pair of p-type source/drain regions; and a second gate electrode formed on the second gate insulating film and containing the selected metal.

10. The semiconductor device according to claim 9, wherein:
the n-channel MIS transistor has a first tungsten layer provided between the first gate insulating film and the first gate electrode; and
the p-channel MIS transistor has a second tungsten layer provided between the second gate insulating film and the second gate electrode.

11. The semiconductor device according to claim 9, wherein a ratio of the composition concentration (atomic %) of the rare-earth metal to the selected metal is in the range of 2.5 to 3.

12. The semiconductor device according to claim 9, wherein a region in which a ratio of the composition concentration (atomic %) of the rare-earth metal to the selected metal is in the range of 2.5 to 3 is located at a portion of the first gate electrode on the side of the first gate insulating film, and has a film thickness of 1.5 nm or larger.

13. The semiconductor device according to claim 9, wherein the rare-earth metal is one of Er, Y, La, Gd, and Yb.

14. The semiconductor device according to claim 9, wherein the alloy of the selected metal and the rare-earth metal is RuEr₃ alloy.

15. The semiconductor device according to claim 9, wherein an insulating film of the same material as the first gate insulating film is formed on side faces of the first gate electrode.

16. The semiconductor device according to claim 9, wherein the second gate electrode has a stacked structure including a Ru layer, a buffer layer formed on the Ru layer and made of one of TiN, TaN, TaSiN, and TiSiN, and a polysilicon layer formed on the buffer layer.

17. The semiconductor device according to claim 16, wherein the buffer layer is made of TiN.

18. A method for manufacturing a semiconductor device, comprising:
forming a gate insulating film on a semiconductor layer;
forming a film containing a metal selected from the group consisting of Ru, Pt, and Rh, the film being provided on the gate insulating film;
forming a film containing a rare-earth metal on the film containing the selected metal; and
forming a gate electrode containing an alloy of the selected metal and the rare-earth metal by causing solid-phase reaction between the selected metal and the rare-earth metal through heat treatment.

19. The method for manufacturing a semiconductor device according to claim 18, further comprising:
stacking a tungsten film on the film containing the selected metal after the film containing the selected metal is formed but before the film containing the rare-earth metal is formed;
forming a tungsten layer at an interface between the selected metal and the gate insulating film by diffusing tungsten through heat treatment; and
removing the remaining tungsten film from the film containing the selected metal.

20. The method for manufacturing a semiconductor device according to claim 18, wherein the heat treatment is carried out at a temperature of 500° C. or lower.
